(19) United States
(12) Patent Application Publication
(10) Pub. No.: US 2026/0334152 A1
(43) Pub. Date: Oct. 22, 2026

(54) CONDUCTIVE BACKSIDE LAYER FOR BOW MITIGATION

(71) Applicant: Lam Research Corporation, Fremont, CA (US)

(72) Inventors: Byung Seok Kwon, Tigard, OR (US); Yanhui Huang, Sherwood, OR (US); Soumana Hamma, Tigard, OR (US); Jeongseok Ha, Portland, OR (US); Fayaz A. Shaikh, Lake Oswego, OR (US)

(21) Appl. No.: 19/100,497

(22) PCT Filed: Jul. 31, 2023
(86) PCT No.: PCT/US2023/029138

§ 371 Date: Jan. 31, 2025

Related U.S. Application Data
(60) Provisional application No. 63/370,001, filed on Aug. 1, 2022.

(51) Int. Cl. H10P 72/72; H10P 14/60; H10P 50/24

(52) U.S. Cl. CPC H10P 72/722; H10P 14/6336; H10P 50/242

(57) ABSTRACT

Provided are methods for keeping a semiconductor wafer chucked to an electrostatic chuck. The semiconductor wafer may have a conductive backside layer deposited on a backside of the wafer through backside deposition. The conductive layer may be able increase the electrostatic force between the wafer and the electrostatic chuck and to counteract internal stress the wafer may have due to frontside processing, keeping the wafer substantially flat.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

During semiconductor processing operations, a semiconductor wafer is typically supported on a pedestal within a processing chamber. The semiconductor wafer may be held in place with respect to the pedestal using a “chuck,” which is a device that augments the force of gravity with some other type of clamping force that increases the friction load between the wafer and the pedestal/chuck in order to prevent relative movement between the wafer and the pedestal/chuck. One type of chuck that is used in such operations is an “electrostatic chuck,” or ESC. Discussed herein are improvements related to the clamping force between a semiconductor wafer and the ESC.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicitly admitted as prior art against the present disclosure.

### SUMMARY

Certain aspects of the disclosure pertain to methods of processing a semiconductor substrate during fabrication of an electronic device. Such methods may be characterized by the following operations: (a) depositing one or more frontside layers on the semiconductor substrate that have a frontside internal stress that, if uncompensated, produces bowing of the semiconductor substrate; and (b) depositing one or more backside layers on the semiconductor substrate that have a backside internal stress that counteracts the frontside internal stress of the one or more frontside layers and reduces or eliminates the bowing, wherein the one or more backside layers have a sheet resistance equal to or less than about 5000 ohm/sq.

In some embodiments, methods further include an operation of (c) clamping, via an electrostatic chuck, the semiconductor substrate with the one or more backside layers. Such methods may additionally include an operation of (d) etching the semiconductor substrate while the semiconductor substrate is clamped to the electrostatic chuck. In some implementations, operations (a), (b), and (c) (and optionally (d)) are each performed in different chambers.

In certain embodiments, the one or more frontside layers comprise a hard mask.

In certain embodiments, the one or more backside layers have a thickness of about 1 μm to about 10 μm. In certain embodiments, the one of the one or more backside layers has a sheet resistance of about 150 ohms/square to about 300 ohms/square. In certain embodiments, at least one of the one or more backside layers comprises a doped polysilicon. Examples of dopants in the doped polysilicon include phosphorus, carbon, boron, tungsten, nitrogen, or any combination of two or more thereof. In certain embodiments, the backside internal stress of the one or more backside layers is about −300 MPa to about 300 MPa.

In some implementations, the operation of depositing one or more backside layers comprises depositing a first backside layer and a second backside layer, disposed further toward the outside of the semiconductor substrate than the first backside layer. In such implementations, the sheet resistance of the first backside layer may be lower than the sheet resistance of the second backside layer.

In some implementations, the operation of depositing one or more backside layers comprises exposing the semiconductor substrate to a process gas comprising a silicon precursor and a dopant precursor. In some cases, the methods additionally include an operation of annealing the semiconductor substrate at a temperature of about 700° C. to about 900° C. to convert a deposited doped silicon layer to a doped polysilicon layer.

Certain aspects of the disclosure pertain to a semiconductor substrate or an electronic device characterized by the following features: (a) one or more frontside layers that have a frontside internal stress that, if uncompensated, produces bowing of the semiconductor substrate or the electronic device; and (b) one or more backside layers that have a backside internal stress that counteracts the frontside internal stress of the one or more frontside layers and reduces or eliminates the bowing, wherein the one or more backside layers have a sheet resistance equal to or less than about 5000 ohm/sq.

In certain embodiments, the one or more backside layers have a thickness of about 1 μm to about 10 μm. In certain embodiments, the sheet resistance of the one or more backside layers is about 500 ohm/sq or less. In certain embodiments, the sheet resistance of the one or more backside layers is about 150 ohm/sq to about 300 ohm/sq.

In certain embodiments, at least one or more backside layers comprises a doped polysilicon. As examples, the doped polysilicon is doped with a dopant comprising phosphorus, carbon, boron, tungsten, nitrogen, or any combination of two or more thereof.

In certain embodiments, the backside internal stress of the one or more backside layers is about −300 MPa to about 300 MPa.

In certain embodiments, the one or more backside layers comprises a first backside layer and a second backside layer, disposed further toward the outside of the semiconductor substrate than the first backside layer, and the sheet resistance of the first backside layer is lower than the sheet resistance of the second backside layer.

Certain aspects of the disclosure pertain to methods of processing a semiconductor substrate during fabrication of an electronic device. Such methods may be characterized by the following operations: (a) receiving a bow compensated semiconductor substrate; (b) clamping via an electrostatically chuck the bow compensated semiconductor substrate; and (c) patterning the bow compensated semiconductor substrate. The bow compensated semiconductor substrate comprises: (i) one or more frontside layers that have a frontside internal stress that, if uncompensated, produces bowing of the semiconductor substrate or the electronic device, and (ii) one or more backside layers having a backside internal stress that counteracts the frontside internal stress of the one or more frontside layers and reduces or eliminates the bowing, wherein the one or more backside layers have a sheet resistance equal to or less than 5000 ohm/sq.

In certain embodiments, the methods include a further operation of (d) etching the bow compensated semiconductor substrate while it is clamped to the electrostatic chuck.

In certain embodiments, the one or more backside layers have a thickness of about 1 μm to about 10 μm. In certain embodiments, the sheet resistance of one of the one or more backside layers is about 500 ohm/sq or less. In certain embodiments, the sheet resistance of one of the one or more backside layers is about 150 ohm/sq to about 300 ohm/sq.

In certain embodiments, at least one of the one or more backside layers comprises doped polysilicon. Examples of the dopant include phosphorus, carbon, boron, tungsten, nitrogen, or any combination of two or more thereof. In certain embodiments, the backside internal stress of the one or more backside layers is about −300 MPa to about 300 MPa.

In certain embodiments, the one or more backside layers comprises a first backside layer and a second backside layer, disposed further toward the outside of the semiconductor substrate than the first backside layer, and the sheet resistance of the first backside layer is lower than the sheet resistance of the second backside layer.

Certain aspects of the disclosure pertain to apparatus comprising: (a) a process chamber; (b) a substrate support; (c) a showerhead; (d) a gas source fluidically connected to the showerhead; and (e) a controller configured to cause: (i) receiving a semiconductor substrate having a frontside layer with a frontside internal stress that, if uncompensated, produces bowing of the semiconductor substrate; and (ii) depositing one or more backside layers on the semiconductor substrate that have a backside internal stress that counteracts the frontside internal stress of the one or more frontside layers and reduces or eliminates the bowing, wherein the one or more backside layers have a sheet resistance equal to or less than about 5000 ohm/sq.

The controller may be further configured to cause one or more of the operations described herein for method aspects of the disclosure.

These and other features of the disclosure will be described in further detail below.

### BRIEF DESCRIPTION OF THE DRAWINGS

FIGS. 1A and 1B show examples of unbowed and bowed semiconductor wafers on an electrostatic chuck.

FIG. 2 shows an example cross section of a semiconductor wafer with an example frontside layer and example backside layer.

FIG. 3 shows an example cross section of a semiconductor wafer on an electrostatic chuck.

FIGS. 4A and 4B shows example semiconductor wafers with an example frontside layer and one or more example backside layer(s).

FIGS. 5A and 5B show an example cross section of a semiconductor wafer on an electrostatic chuck.

FIG. 6 is a process flow diagram illustrating certain operations in methods for deposition.

FIGS. 7A and 7B is a graph illustrating results of film performance after an annealing operation.

FIG. 8 is a process flow diagram illustrating certain operations in semiconductor wafer processing.

FIGS. 9A-E are schematic depictions of example cross sections of a semiconductor wafer during semiconductor processing according to various embodiments.

FIG. 10 is a process flow diagram illustrating certain operations in semiconductor wafer processing.

FIGS. 11A-G are schematic depictions of an example cross section of a semiconductor wafer depictions during semiconductor processing according to various embodiments.

FIGS. 12A and 12B show a block diagram of an example substrate processing system.

FIG. 13A shows an example cross section of an edge of a shower-pedestal.

FIG. 13B shows a top view of an example carrier ring.

FIG. 14 shows a schematic of an example process system that may be used to perform the methods described herein.

### DETAILED DESCRIPTION

### Terminology

The following terms are used throughout the instant specification:

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, 300 mm, or 450 mm. Examples of semiconductor substrate materials include silicon (Si), gallium arsenide (GaAs), and silicon germanium (SiGe). Besides semiconductor wafers, other workpieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The workpiece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

An “electrostatic chuck” (ESC), as used herein, refers to a chuck that uses electrostatic force to clamp a wafer to the chuck during processing. The ESC may use one or more electrodes. Voltages may be applied to each of the one or more electrodes. The applied voltage may cause current to flow, thereby causing charge to migrate through a dielectric layer between the chuck and a wafer or substrate being processed. Opposite charges accumulated at an electrode relative to the wafer therefore cause the wafer to be gripped or clamped to the chuck by the electrostatic force. In some cases, the electrodes may be integrated into the ESC or may be separate from the ESC. In some embodiments, the ESC may refer to the electrodes that generate the electrostatic force.

A “platen” as used herein refers to a top surface of an ESC on which a wafer undergoing fabrication is positioned. There may be a gap between the wafer and the platen surface (e.g., the upper surface), which is generally referred to herein as “d.”

A “pedestal” as used herein may refer to a structure or housing that supports or includes the platen.

“Wafer bow” as used herein may refer to a deformation of a wafer. The deformation may have radial and/or azimuthal components. Examples of types of wafer bow include dome shapes, dish shapes, and potato chip shapes. Wafer bow may occur during fabrication, for example, as a result of stress to the wafer during deposition of materials on an active surface of a wafer substrate. Wafer bow may occur during various types of fabrication, such as when large stacks of materials are deposited. Wafer bow may cause complications in subsequent processing steps. For example, the wafer may fail to chuck correctly if an amount of bowing is too large. Moreover, some processing steps (e.g., photolithography) may produce poor results if performed on a wafer that is excessively bowed.

Wafer bow may be measured as a deviation of the mean or median distance of the surface of the wafer to a reference plane. The point of the median surface of the wafer may be the center point (e.g., in the case of concave or domed bowing), or an edge point of the wafer and/or an average edge point of the wafer (e.g., in the case of warping or convex bowing).

“Wafer declamping,” as used herein, refers to a state where a wafer is no longer clamped to a platen of an electrostatic chuck (ESC). As used herein, when wafer bow is detected, or more than a threshold amount of wafer bow is detected, during fabrication or processing of a wafer, the wafer can be considered declamped from the ESC. It should be noted that, as used herein, wafer bow may be associated with a numeric value that indicates a degree of bowing. By contrast, wafer declamping may be a binary classification that indicates whether or not a wafer is clamped to the platen.

### Electrostatic Chucks

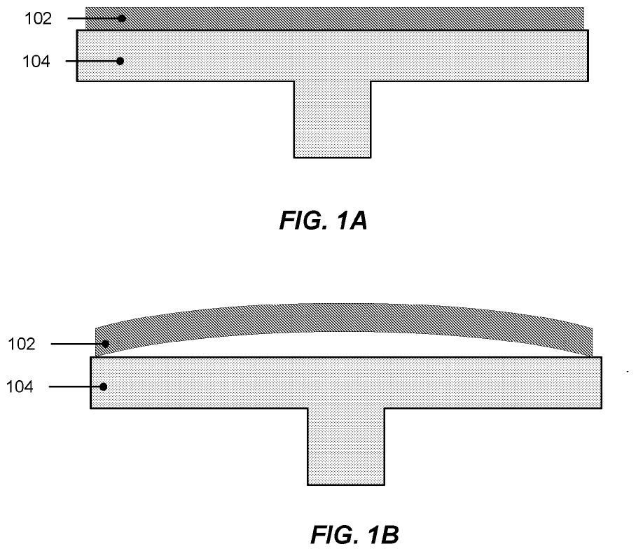

An electrostatic chuck (ESC) may be used to secure a wafer in place within a semiconductor processing chamber by an electrostatic chuck. FIG. 1A shows a semiconductor substrate 102 on an ESC 104. Some ESCs hold a wafer, which may be electrostatically charged as a result of processing operations, in place by applying a single direct current (“DC”) voltage to one or more clamping electrodes within the ESC such that the clamping electrode(s) and the wafer act as all or part of a capacitive circuit. In some embodiments such as some monopolar ESCs, the capacitive circuit is completed by the existence of a plasma within the chamber. The clamping electrode(s) are typically planar structures that are parallel to the overall plane of the wafer and often extend across a region commensurate with the wafer size. The electrostatic force that arises due to the capacitive effect provides the clamping force.

Some ESCs can clamp even when a plasma is not present, as may be the case in chambers that do not produce plasma environments during processing. In such implementations, the plasma cannot be relied upon to complete the capacitive circuit, and the ESC electrodes may instead include one or more cathodes and one or more anodes. The anodes and cathodes may occupy different regions of the ESC that face towards the wafer, e.g., an anode and cathode that occupy opposing semicircular regions under the wafer or an anode or a cathode arranged as a center circular electrode and a concentric outer electrode under the wafer acting as an anode. The anode and the cathode in such ESCs are electrically isolated from one another within the ESC, but when a wafer is placed on the ESC, the wafer completes two capacitive circuits-one where the wafer is the anode to the ESC cathode, and one where the wafer is the cathode to the ESC anode. Such ESC designs may be called bipolar (in the case of one anode and one cathode) or multipolar (in the case of three or more electrodes).

ESCs may have a dielectric layer or other insulator interposed between the clamping electrode(s) and the wafer; this dielectric or insulating layer serves to prevent a short circuit between the clamping electrode(s) and the other half of the capacitive circuit(s), i.e., the wafer, and defines the gap that governs the capacitance characteristics of the capacitive circuit formed by the ESC and the wafer. In some embodiments, an ESC has dimples or minimum contact areas (MCAs) that support the wafer but leave a significant gap between the wafer and the electrostatic chuck over much of the wafer's surface area. This gap may serve, at least partially, as the dielectric of the capacitor.

Other common features of ESCs include, depending on the particular needs of a semiconductor process, gas distribution holes and lift pinholes. The gas distribution holes may be used to flow thermally conductive, inert gas, such as helium, into the gap between the wafer and the ESC during processing. Since the wafer is clamped to the ESC by an electrostatic force, the surfaces of ESCs are frequently not completely flat since it may be desirable to reduce the amount of actual wafer-to-ESC contact. For example, the top surface of the ESC may have one or more thin, concentric raised rings and one or more thin raised radial spokes that actually contact the wafer, but the interstices between those raised rings and spokes may not contact the wafer. During processing in vacuum or near-vacuum environments, this may result in a concentration of heat flow through the regions of the wafer that are in actual contact with the ESC, which may cause non-uniformities in the wafer. To prevent this, the thermally conductive, inert gas may be flowed into these interstices to provide a distributed thermally conductive path that reduces the heat flow concentration through the physical contact areas. Even in flat-top ESCs that do not have raised/recessed areas by design, at a microscopic level, the physical contact between the wafer and the ESC may be intermittent, so there may also be a heat transfer benefit to introducing a thermally conductive gas between the wafer and the ESC even in these cases. The thermally conductive gas may also serve to provide an additional layer of protection against process gases-if the thermally conductive gas flows into the gap between the wafer and the ESC during processing, it will flow towards the wafer edge in order to escape, which prevents process gases from reaching the underside of the wafer and the portion of the ESC underneath the wafer, which protects these regions from undesired etch or deposition, as the case may be. Lift pinholes may be provided to allow lift pins to extend through the ESC and lift the wafer off of the ESC. The ESC lift pins may be configured to fully retract into the ESC lift pin holes such that in one position, the ESC lift pins do not extend past the ESC. These lift pins and their corresponding holes, among other things, allow a robot end-effector or other mechanical device to place and/or remove a wafer from the ESC without contacting and/or interfering with the ESC.

### Bowed Wafers

Semiconductor device fabrication often involves deposition of a stack of layers on a wafer substrate. Typically, most deposition and other processing to form the devices occurs on one side of the substrate, often referred to as the front face or frontside of a wafer. As the deposited layers build up, they can introduce stress in the wafer. A large net compressive or tensile stress can cause the wafer to bow, which is undesirable.

Bowing is especially likely to occur where large stacks of materials are deposited, for example, in the context of 3D-NAND devices. FIG. 1B shows a bowed semiconductor substrate 102 placed on an ESC 104. Where bowing is significant, it can deleteriously affect subsequent processing steps. For instance, the wafer may fail to chuck correctly if the bowing is too great. Further, certain processing steps (e.g., photolithography) are very precise and produce poor results if the wafer is not substantially flat. The problem may be manifest as lithography defocus.

One example stack that may cause these problems is a stack having alternating layers of oxide and nitride (e.g., silicon oxide/silicon nitride/silicon oxide/silicon nitride, etc.). Another example stack likely to cause bowing includes alternating layers of oxide and polysilicon (e.g., silicon oxide/polysilicon/silicon oxide/polysilicon, etc.). Other examples of stack materials that may be problematic include, but are not limited to, tungsten and titanium nitride.

The materials in the stacks may be deposited through chemical vapor deposition (CVD) techniques such as plasma enhanced chemical vapor deposition (PECVD), low pressure chemical vapor deposition (LPCVD), metal organic chemical vapor deposition (MOCVD), atomic layer deposition (ALD), plasma enhanced atomic layer deposition (PEALD), or through direct metal deposition (DMD), etc. These examples are not intended to be limiting. Certain disclosed embodiments may be useful whenever wafer stress and/or bowing are induced due to material present on the front side of the wafer.

Various techniques have been devised for combatting bowing. When bowing is modest, electrostatic clamping may overcome the bow by flattening an otherwise bowed wafer when it is clamped. When bowing is more severe, deposition processes may be tuned to reduce or counteract internal stresses in deposited layers. However, any such tuning should not interfere with process requirements for fabricating devices. One commonly used technique to counteract bowing deposits a film on the back side of the wafer.

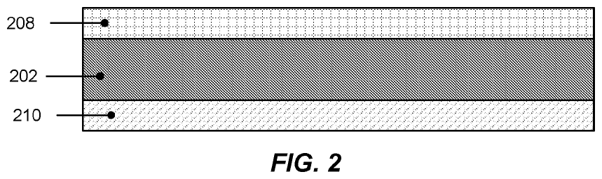

Backside deposition may form a high-stress dielectric film. FIG. 2 is a cross-sectional view of a wafer 202 with a frontside layer 208 and a backside layer 210. If the backside layer 210 has opposite internal stress and of comparable magnitude to the internal stress created on the frontside, the backside film effectively counteracts and corrects the bow.

A typical scenario might involve the following:
1. Deposit one or more frontside layers with high internal stress that produce significant bowing (chamber A).
2. Deposit a backside layer having internal stress that counteracts the internal stress of the one or more frontside layers and reduces or eliminates the bowing (chamber B).
3. Pattern the frontside of the unbowed substrate by photolithography.
4. Etch the unbowed, patterned substrate (chamber C).
Chambers A, B, and C may each be different, although this is not always the case. For example, in some embodiments, chambers A and C are the same.

Examples of high-stress backside films currently in use include the following: amorphous silicon, silicon oxide, silicon nitride, and silicon oxynitride. Current backside films have high internal stress and are able to mitigate the stresses imparted on the wafer from the frontside layers to reduce or eliminate the wafer bow. Generally, backside layers are made of dielectric films with high stress and very high resistivity.

Until relatively recently, the backside film thickness remained relatively thin (e.g., <2 μm). Thus, downstream processes at previous technology nodes did not normally experience issues addressed by embodiments herein. However, modern IC fabrication techniques may produce substrates having frontside layers with much higher internal stresses compared to previous nodes. One fabrication technique causing this issue is the use of thick hardmask layers in operations where the etch selectivity between the hardmask and etched material is limited but yet deep trenches or vias are etched.

Due to the higher internal stresses, certain issues arose. These include: (i) partial/full dechucking due to thick dielectric films causing the clamping force to considerably weaken, and/or (ii) partial/full dechucking due to considerably higher bow resulting from the significantly thicker frontside. To combat this, one may increase the clamping force by increasing the ESC chucking voltage. However, increasing the ESC chucking voltage is confined to a tight window of control. If the voltage is too low, the ESC clamping force is too low, causing wafers to slip and/or dechuck. If the voltage is too high, punch-through damage is observed at the wafer backside, destroying the wafer. Alternatively, one may increase the contact area by increasing the number of dimples and/or increasing the surface area of the dimples. However, ESCs with an increased contact surface improves clamping force but significantly increases the risk of wafers sliding on the ESC due to entrapped air between the backside of the wafer and the platen of the ESC.

As a result, some techniques require the backside film thickness to be about 4× that of the previous node (e.g., ~7~8 μm). Returning to FIG. 2, as the overall bow of wafers significantly increases due to, e.g., thicker frontside layer 208, the backside layer 210 correspondingly significantly increases to compensate for the overall bow. Although overall bow can be addressed by thicker backside layers 210, one issue that was non-existent with thinner backside film has started to occur.

Processing that utilizes a high-stress dielectric film on the backside of the wafer creates a charge vacant space layer between the backside of the wafer and the pedestal due to the insulating characteristic of the dielectric layer. A thicker dielectric film results in larger charge vacant layers, which can decrease the clamping force generated between a wafer and an ESC.

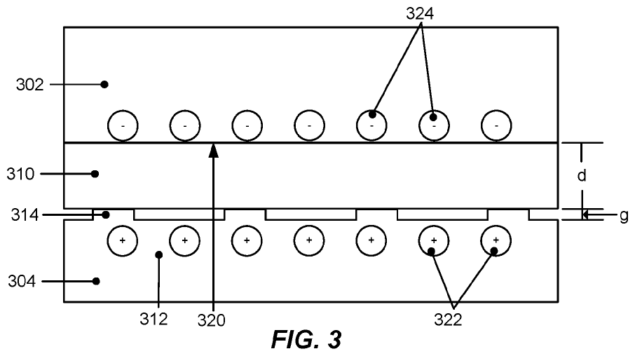

FIG. 3 is a cross-sectional view showing a wafer 302 with a dielectric backside layer 310 on an ESC 304. The backside layer 310 on the wafer 302 sits on a platen 312 of the ESC 304. In the embodiment shown, the platen 312 has dimples 314 to prevent air pockets from being created when placing the wafer 302 on the ESC 304. As described above, an ESC holds the wafer through the electrostatic charge. The platen 312 of the ESC 304 and wafer 302 each act as a charged plate in a capacitor. In the embodiment shown, the platen 312 is positively charged, while the wafer 302 is negatively charged. The electrostatic clamping force between the wafer 302 and the ESC 304 may be represented by the following equation,

$$F = \frac{A}{2} ε {( \frac{V}{d + g} )}^{2} .$$

Thus, the electrostatic clamping force between the wafer is a function of the distance between the positively charged platen 312 and negatively charged wafer 302. As the distance increases, the electrostatic clamping force decreases exponentially. In the example of FIG. 3, the distance between the two charged plates includes the air gap (g) between the backside layer 310 and the platen 312 plus the backside layer thickness (d). As the dielectric backside layer 310 thickens, the separation distance between the charged plates, i.e., the surface of platen 312 and the conductive surface of wafer 302, increases, reducing the electrostatic chucking force between the two.

Due to thicker dielectric backside films, downstream processes which utilize electrostatic chucking may suffer from partial or complete ESC chucking failure as the clamping force between the pedestal and wafer backside is weakened. In addition, a thick dielectric film on the wafer backside can cause a chucking failure due to trapped charges, which cannot dissipate in the dielectric film.

### Conductive Layer

Disclosed herein are methods, systems, and techniques for maintaining wafer chucking on an ESC and reducing wafer bow even for wafers with substantially high internal stresses. In particular, the wafer may have a conductive backside layer. The conductive backside layer may reduce the gap between a charged platen surface of an ESC and a charged surface connected to the wafer substrate, increasing the electrostatic chucking force between the wafer and the ESC. In certain embodiments, the conducting backside layer is used together with an insulating backside layer.

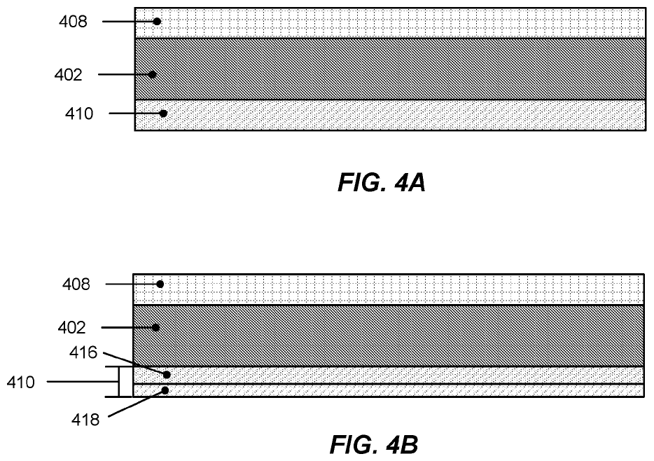

Shown in FIG. 4A is a wafer 402 with a frontside layer 408 and a conductive backside layer 410. As discussed above, due to modern IC fabrication techniques, the frontside layer 408 may have higher internal stress compared to previous fabrication nodes. Accordingly, the conductive backside layer 410 typically has a correspondingly high internal stress. By producing a conductive backside layer 410 with corresponding internal stress, the backside layer may reduce and/or remove any wafer bow due to internal stress produced by the frontside layer 408. In some cases, the frontside layer 408 has an internal stress of about −1000 MPa to 1000 MPa. If left uncompensated, the wafer 402 may have a bow about 200 μm to about 1 mm. Wafers with a bow greater than about 150 μm or greater than about 200 μm may cause issues in subsequent fabrication steps. For example, a wafer with a bow over 150 μm may fail to chuck correctly to an ESC. Many process steps, such as photolithography, require high precision, and wafers that are not substantially flat produce poor results due to focus variations and other optical issues.

In many embodiments, the conductive backside layer has an internal stress that matches or approximately matches the internal stress of the frontside layer(s). Thus, in some embodiments, the internal stress of the conductive backside layer 410 is about −1000 MPa to 1000 MPa.

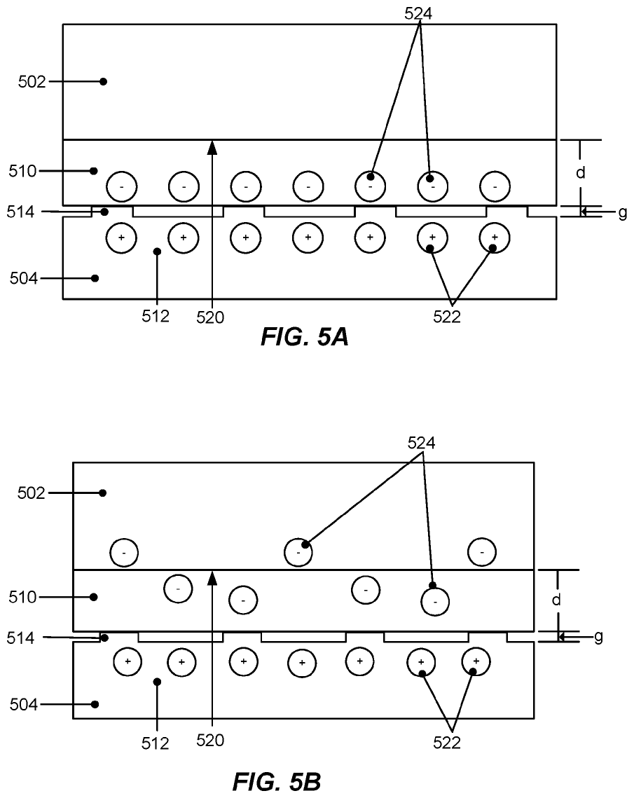

Because it decreases the effective distance between the conductive portion of the wafer and the ESC, the conductive backside layer increases the clamping force between a wafer and an ESC. Shown in FIG. 5A is a cross-section illustrating how charges are located in a situation of a wafer 502 with a conductive backside layer 510 on an ESC 504. The ESC 504 has a platen 512 with dimples 514. The dimples 514 are in contact with the conductive backside layer 510. In the embodiment shown, the platen 512 of the ESC 504 and the conductive backside layer 510 each act as a charged plate in a capacitor. The platen 512 is a positively charged plate, and the conductive backside layer 510 is a negatively charged plate. The distance between the positively charged platen 512 and the negatively charged surface of the conductive backside layer 510 is the air gap (g) caused by dimples. By reducing the distance between the positively charged platen 512 and the charged surface connected to the wafer 502, i.e., the conductive backside layer 510, the electrostatic clamping force remains relatively strong. By having a conductive backside layer 510, the thickness of the conductive backside layer 510 is a minimal concern in regard to keeping the wafer 502 chucked to the ESC 504. In some embodiments, the backside conductive layer 410 may have a thickness about 1 μm to 10 μm, e.g., about 1.5 μm to 3 μm, about 3 μm to 6 μm, or about 6μ m to 9μ m.

FIG. 5B shows a different embodiment with a conductive backside layer 510. As will be discussed below, the conductive backside layer 510 may not be a perfectly conductive material. In the equation for electrostatic clamping force,

$$F = \frac{A}{2} ε {( \frac{V}{α d + g} )}^{2} ,$$

a represents the conductivity of the conductive backside layer 510, d represents the thickness of the backside layer, and g represents the gap between the bottom of the backside layer and the platen 512. When the conductive backside layer 510 is not highly insulating, some of the negative charge 524 remains on the wafer 502 closer to a backside surface 520 of the wafer 502 and some of the negative charge moves onto the conductive backside layer 510. As the conductive layer becomes more conductive, a higher percentage of the negative charge 524 moves off the wafer 502, onto the conductive backside layer 510 towards the ESC 504, and closer to the positively charged platen 512, reducing the distance between the charges. In cases where the conductive backside layer 510 is highly conductive, a goes to 0, and the negative charge concentrates on the conductive backside layer 510. When the conductive backside layer 510 is highly conductive, the distance between the two charged plates is the air gap (g) between the platen 512 and the backside layer 510. In cases where the conductive backside layer 510 is highly insulating, a goes to 1, and the negative charges remain on the backside surface 520 of the main portion of wafer 502, weakening the electrostatic clamping force between the wafer 502 and the ESC 504 as the backside layer thicknesses increase, as shown in FIG. 3. The distance between the two charged plates is the distance between the backside surface 520 of the wafer 502 and the platen 512 (d+g). In reality, α is somewhere between 0 and 1, depending on the conductivity of the conductive backside layer 510. To ensure there is enough electrostatic clamping force to secure the wafer 502 to the ESC 504, a higher conductive backside layer with low resistance is desirable.

The conductive backside layer may be made from various materials. In certain embodiments, it is made from a doped polycrystalline film. Examples of doped polycrystalline films included doped polysilicon films. The dopant may be either p-dopant or an n-dopant. Examples of dopants include carbon, boron, tungsten, phosphorus, nitrogen, arsenic, and any combination of two or more of these. For example, a conductive backside layer may be a phosphorus-doped polysilicon film.

The conductive backside film thickness may have a within-wafer (WiW) nonuniformity of about 15% or less. In some embodiments, the WiW nonuniformity is about 7% or less. In still some other embodiments, the WiW nonuniformity is about 3% or less. In some embodiments, the conductive backside layer has a sheet resistance of about 1000 ohm/sq or less. In some other embodiments, the conductive backside layer has a sheet resistance of about 500 ohm/sq or less. In some embodiments, the conductive backside layer has a sheet resistance to about 250 ohm/sq or less. In one example, the conductive backside layer has a sheet resistance of about 150 ohm/sq to about 300 ohm/sq.

Depending on the application, in some embodiments, the wafer may have a backside layer that is homogenous, e.g., it comprises a single material. In some embodiments, the backside layer may be heterogeneous, e.g., having multiple materials. In some cases, the multiple materials may form multiple layers, each having a composition. In some embodiments, the multiple layers include a first backside layer that abuts the base semiconductor substrate or is closer to the base semiconductor substrate than a second backside layer. In other words, the second backside layer is disposed further toward an outside of the complete semiconductor substrate than the first backside layer. In such embodiments, the first backside layer may be more conductive (or have a lower sheet resistance) than the second backside layer.

FIG. 4A shows a wafer 402 with a homogenous backside layer 410. The wafer 402 has a single backside layer made of a highly conductive material, such as doped amorphous silicon. In some embodiments, the backside layer 410 is made of multiple sublayers. The sublayers may be made of a single material, such as the highly conductive material, or they made of different materials or have different compositions.

FIG. 4B shows a wafer 402 with a heterogeneous backside layer 415 made of two or more materials. In the example shown, the heterogeneous backside layer 415 has two backside sublayers, a first backside layer 416 and a second backside layer 418 disposed further toward an outside of the semiconductor substrate than the first backside layer. The first backside layer 416 may have one or more sublayers of a highly conductive material, e.g., doped polysilicon, in contact with or very close to the wafer's 402 bottom surface 420, and the second backside layer 418 may have one or more sublayers of less conductive or dielectric material on the backside of the substrate. In some embodiments, the backside may have three or more layers, optionally made of different materials. In certain embodiments, when the wafer 402 has a heterogeneous backside, the most conductive layer may be positioned closest to the wafer 402. In some embodiments, the backside layer may be in direct contact with the backside surface of the wafer 402. In some embodiments (not shown), a thin layer of silica (USG) or another dielectric material may be located between the first backside layer 416 and the surface of the wafer 402. The frontside layer 408 in both FIG. 4A and FIG. 4B is depicted as a single layer. It should be appreciated that the frontside layer 408 may be a single layer or a multilayer stack.

### Backside Deposition Process

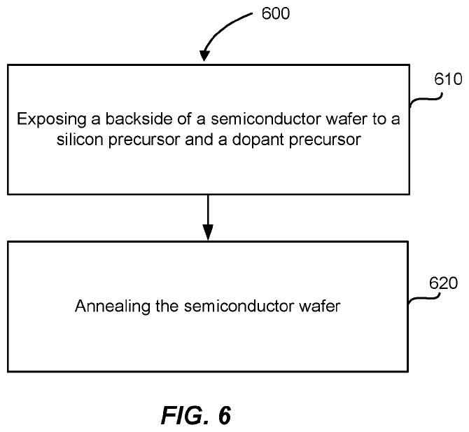

FIG. 6 is a process flow diagram illustrating an example method for depositing a conductive layer on the backside of a semiconductor wafer. Method 600 begins with exposing a backside of a semiconductor wafer to one or more precursors of a conductive backside film in an operation 610. The exposure is performed in a manner that deposits the conductive film on the backside of the wafer. In certain embodiments, the deposited film is doped amorphous silicon, and the precursors include a silicon precursor and a dopant precursor. The remainder of the description of this process flow refers to doped amorphous silicon, but other conductive materials may be used. In various embodiments, the deposition process is similar to that employed conventionally to deposit insulating backside films, except that the process gas includes precursors for a conductive film. Examples of deposition processes for forming the backside layer include chemical vapor deposition (CVD), atomic layer deposition (ALD), physical vapor deposition (PVD), epitaxial growth, and plasma enhanced versions of any of these. A dopant precursor may be present in the process gas at a concentration that is about 0.1 to 99% by volume (or about 0.1 to 20%) of the concentration of a silicon precursor. Examples of dopant precursors include phosphine (PH₃), propene (C₃H₆), diborane (B₂H₆), tungsten hexafluoride (WF₆), and ammonia (NH₃). In some embodiments, the dopant precursor may be a combination of two or more thereof. Examples of silicon precursors include silane (SiH₄) and variants thereof (SiₓH_{y}) such as disilane or trisilane.

After the film is deposited, the wafer may be annealed in an operation 620. For example, a deposited silicon film may be annealed to convert the silicon from an amorphous morphology to a polycrystalline morphology. Annealing may be conducted at a temperature of about 550° C. to 950° C., e.g., about 700° C. to 900° C. Annealing may be conducted for a time duration of about 15 to 60 minutes. Annealing may be conducted under an inert atmosphere. The annealing process of the film on the backside of the semiconductor wafer reduces the resistance of the film making the layer conductive, e.g., having a sheet resistance of about 5000 ohm/sq or less. In some embodiments, the annealing process may reduce the sheet resistance to about 500 ohm/sq or less. In some embodiments, the annealing process may reduce the sheet resistance to about 250 ohm/sq or less. The sheet resistance may be about 150 ohm/sq to 300 ohm/sq. Annealing may also improve the film uniformity so that the film has within wafer non uniformity of about 15% or less. In some embodiments, the annealing process may reduce the stress of the backside layer so that the internal stress is about 500 MPa to 500 MPa.

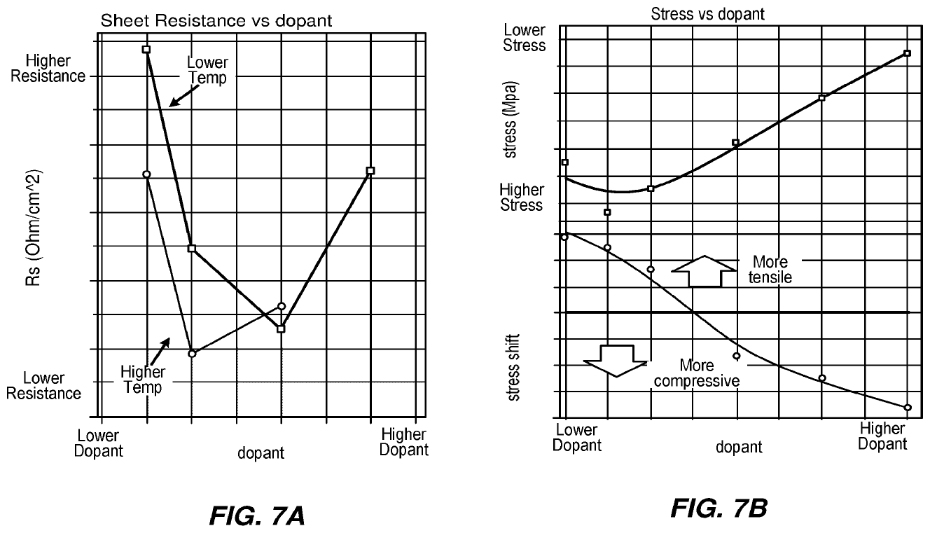

FIG. 7A shows the sheet resistance, and FIG. 7B shows the internal stress of a backside film deposited using, e.g., the operations described in FIG. 6. FIG. 7A shows an example of the relationship between the sheet resistance and dopant concentration of an amorphous silicon film after it is annealed. The film may be tuned by adjusting the amount of dopant in a process gas and the temperature the film is annealed at. The graph shows the sheet resistance of film annealed at two different temperatures; the red line represents a film annealed at a higher temperature than the film represented by the blue line The sheet resistance of each film annealed at each temperature is compared to the amount of dopant used in the film. In both films, as the dopant is introduced, the resistance in each film decreases. A certain concentration of dopant allows the film to reach its lowest resistance. As the amount of dopant introduced to the film continues to increase, the resistance of the film may start to increase, as shown in each graph in FIG. 7A.

FIG. 7B compares the stress to the dopant levels for the film annealed at the lower temperature. As shown, the internal stress of the film peaks for a particular amount of dopant. As more dopant is introduced to the film, the internal stress within the film is reduced. At higher levels of dopant, the internal stress may be reduced. The amount of dopant introduced to the film may vary depending on the internal stress desired in the backside film to counteract the frontside layer internal stress.

### Overall Process Sequence

Generally, an overall process utilizing the backside films of the present disclosure begins by forming a bow compensated substrate having a backside film followed by an operation that electrostatically clamps the bow compensated substrate during a subsequent operation. Examples of subsequent operations include photolithography, etching, planarization, further deposition, and the like. Example etching processes include plasma etching, reactive ion etching, chemical etching, atomic layer etching, and the like. Examples of further deposition operations include CVD (thermal and/or plasma enhanced), ALD, and epitaxial growth.

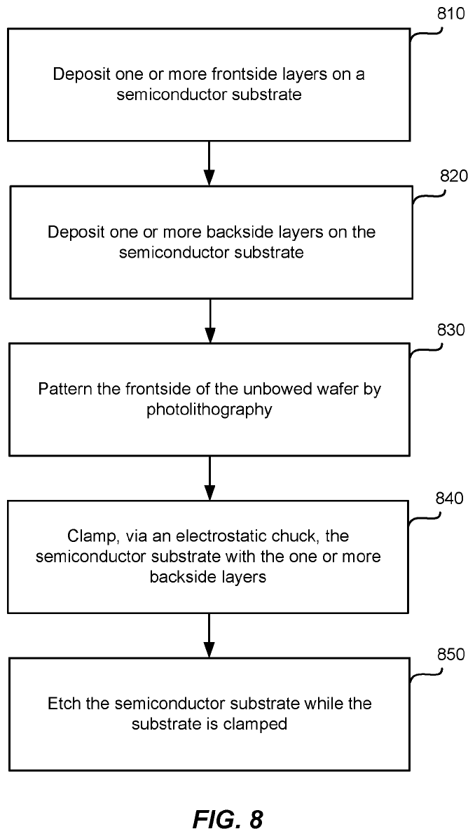

FIG. 8 shows a first example process of processing a semiconductor wafer. FIG. 8 starts with depositing one or more frontside layers on a semiconductor wafer in operation 810. The frontside layer may be deposited by using ALD, plasma enhanced ALD, CVD, plasma enhanced CVD, PVD, or epitaxial growth. ALD is a surface-mediated deposition technique in which doses of a precursor and a reactant are sequentially introduced into a first chamber. In an example CVD process, a precursor and a reducing agent are in vapor phase together in the first chamber. Plasma enhanced processes may be used to fill features at lower temperatures and/or increase deposition rates. The deposited frontside layer(s) may be a single layer or may be multiple layers. The frontside layer(s) may have internal stress on the semiconductor wafer and, if left uncompensated, may cause the semiconductor wafer to bow. In some embodiments, the internal stress of the deposited frontside layer(s) may be about −1000 MPa to about 1000 MPa. In some embodiments, the internal stress of the deposited frontside layer(s) is −450 MPa to about 450 MPa, e.g., about −300 MPA to about 300 MPa.

After the one or more frontside layers are deposited on the semiconductor wafer, one or more backside layers are deposited on the semiconductor wafer in operation 820. The backside layer may be deposited using the process flow described above in FIG. 6. The backside layer may be deposited by using ALD, plasma enhanced ALD, CVD, plasma enhanced CVD, or epitaxial growth. The deposition may take place in a second chamber designed for deposition on a backside of a wafer. At least one of the one or more deposited backside layers is a conductive layer. The conductive layer may be, for example, a doped polysilicon. It may be doped with the dopants described elsewhere herein. The conductive layer, as discussed above, may have a sheet resistance of about 5000 ohm/sq or less, e.g., about 1000 ohm/sq or less, about 500 ohm/sq or less. In some embodiments the conductive layer may have a sheet resistance of about 150 ohm/sq to about 300 ohm/sq. The one or more backside layers may produce internal stress. In some embodiments, the produced internal stress may be able to counteract the internal stress created by the frontside layers deposited in 810. In these embodiments, the stress from the frontside layer causes the semiconductor wafer to bow. The deposited backside layer may produce internal stress that opposes the stress caused by the frontside and reduces and/or removes the wafer bow caused by the stress from the frontside layer, thus causing the wafer to remain substantially flat. In some embodiments, the deposited backside layer may have internal tensile stress of about −1000 MPa to about 1000 MPa, e.g., about −450 MPa to −450 MPa, about −300 MPa to about 300 MPa. As discussed above, the backside may be a single layer or may be multiple layers. In some embodiments, the backside is homogenous. In some embodiments, the backside layer may be heterogeneous. In these embodiments, a first sublayer may have a lower sheet resistance than a second sublayer. In some embodiments, the first sublayer is between the second sublayer and the wafer substrate. In some embodiments, the second sublayer is between the first sublayer and the wafer substrate. In both homogenous and heterogenous embodiments, at least a portion of the backside layer is conductive.

In operation 830, after the backside layer is deposited, the frontside of the unbowed wafer is patterned by, e.g., photolithography. The frontside may include a target layer and a hardmask. The hardmask may be patterned in the photolithography step to protect selective areas of the frontside layer in subsequent etching operations.

In operation 840, the semiconductor wafer is placed in an etch chamber and clamped to the ESC via one or more of the backside layers. In some embodiments, the etch chamber may be the same as the first chamber where operation 810 occurs. In some embodiments, the etch chamber may be a different chamber than the first chamber. As discussed in operation 820, at least a part of the backside layer is a conductive layer. The semiconductor wafer may be clamped to the ESC by the conductive layer. As discussed above, the conductive layer may act as a first plate, and the ESC may act as a second plate of a capacitator. The charge between the two plates produces an electrostatic force able to produce a clamping force between the backside layer of the semiconductor wafer and the electrostatic chuck. This clamping force may hold the semiconductor wafer on the ESC through subsequent processing operations. To be clamped to the ESC, the semiconductor wafer should be substantially flat, e.g., have a bow of about 1 mm or less. However, wafers with bow values in the higher end of this range, e.g., about 200 μm to 1 mm, require a higher voltage ESC, which may damage the wafers.

In operation 850, the semiconductor wafer is etched while being clamped to the ESC. The etching process may occur in the etch chamber. In some embodiments, the etch chamber may be the same as the first chamber where operation 810 takes place. In some embodiments, the etch chamber may be a different chamber than the first chamber. During the etch process, the semiconductor wafer may be clamped to the ESC. Example etching processes include plasma etching, reactive ion etching, chemical etching, atomic layer etching, and the like. The etch may selectively etch portions of the frontside layer.

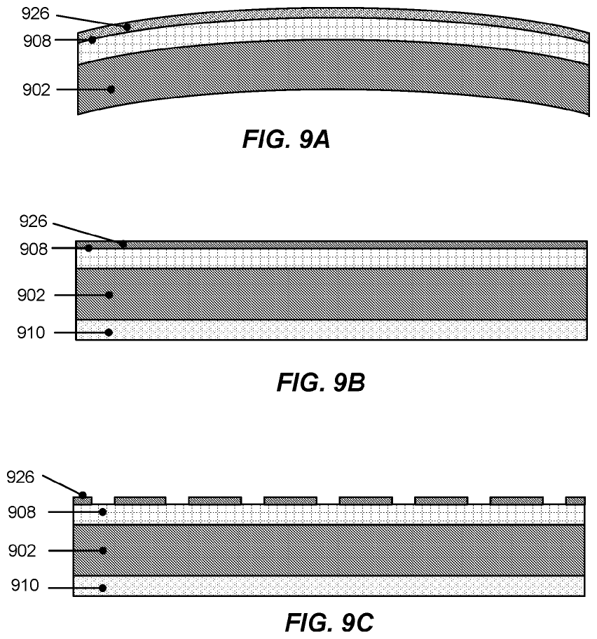

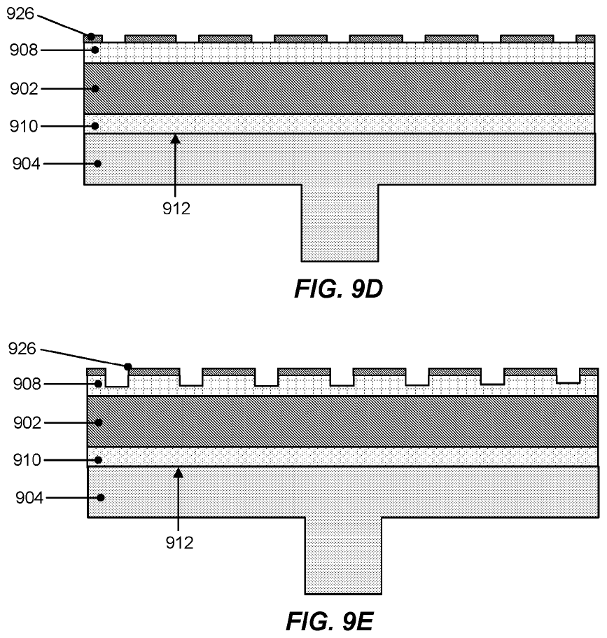

FIGS. 9A-9E show a schematic of the method depicted in FIG. 8. FIG. 9A shows a semiconductor wafer 902 after the frontside layer 908 is deposited in operation 810. The frontside layer 908, while depicted as a single layer in FIG. 9A, may be a single layer or multiple sublayers. In some embodiments, the deposited frontside layer may include a hardmask 926. The deposited frontside layer 908 may have internal stress, which may cause bowing in the wafer. In the example in FIG. 9A, the frontside layer 908 and the semiconductor wafer 902 are bowed, indicating the deposited frontside layer has internal stress.

FIG. 9B shows the semiconductor wafer 902 after the backside layer 910 is deposited in operation 820. The backside layer 910 has internal stress able to counteract the internal stress of the frontside layer 908 and may cause the semiconductor wafer 902 to become substantially flat, as shown in the figure. The backside layer 910, while shown as a single layer in FIG. 9B, may be a single layer or multiple sublayers. Depending on the application, in some embodiments, the backside layer 910 may be a homogenous backside layer, e.g., a single material. In these embodiments, the backside layer 910 is made of a conductive material. In some embodiments, the backside layer 910 may be heterogeneous, e.g., composed of two or more materials. When the backside layer is heterogeneous, at least one of the materials is a conductive material. In some embodiments of the heterogeneous backside layer, one of the materials may be a dielectric material.

FIG. 9C shows the semiconductor wafer 902 after the frontside layer 908 is patterned by photolithography in operation 830. In the embodiment shown, the frontside layer 908 has a hardmask 926. The photolithography operation patterns the hardmask 926 in preparation for subsequent etch operations.

FIG. 9D shows the semiconductor wafer 902 clamped to the ESC 904. The semiconductor wafer 902 is held by the electrostatic force between the ESC 904 and the backside layer 910. The electrostatic force secures the semiconductor wafer 902 to the ESC 904, preventing the semiconductor wafer from dechucking or slipping off the ESC in subsequent operations.

FIG. 9E shows the semiconductor wafer 902 after the etch operations in 850 take place. As shown, the semiconductor wafer 902 may be clamped to the ESC 904. The etch operation may be, for example, plasma etching, reactive ion etching, chemical etching, or atomic layer etching. In the embodiment shown, the etch operation etches the frontside layer 908, following the pattern created in the hardmask 926 by the photolithography in operation 830.

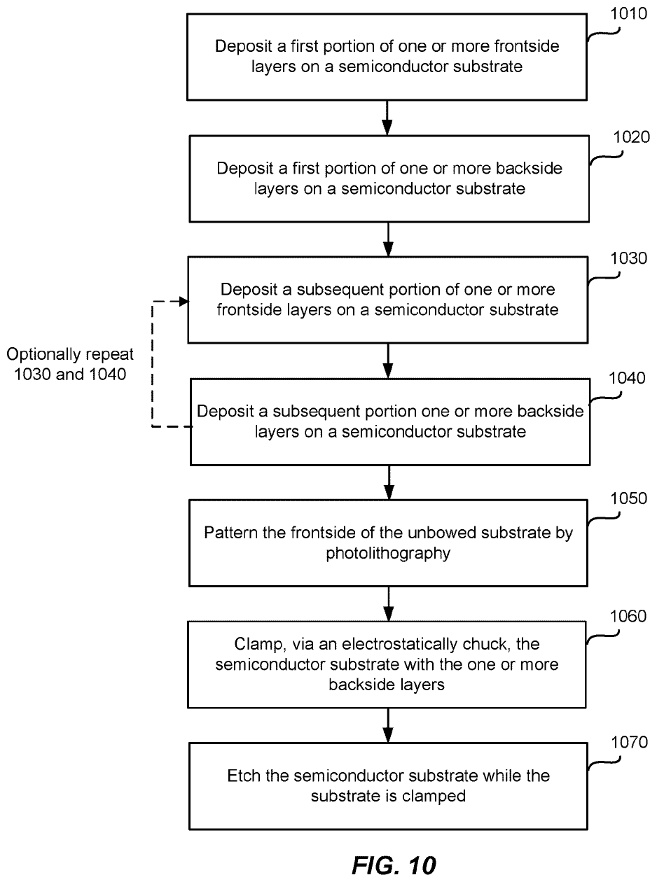

FIG. 10 shows a second example of processing a semiconductor wafer. FIG. 10 starts with depositing a first portion of one or more frontside layers on a semiconductor wafer in operation 1010. The frontside layer may be deposited by ALD, plasma enhanced ALD, CVD, plasma enhanced CVD, or epitaxial growth. In some embodiments, the deposited frontside layer is a single layer. In some embodiments, the deposited frontside layer is multiple layers. The frontside may produce internal stress on the semiconductor wafer and, if left uncompensated may cause the semiconductor wafer to bow. In some embodiments, the internal stress of the deposited frontside layer(s) may be similar to that discussed above in FIG. 8, a force of about −1000 MPa to 1000 MPa, e.g., about −450 MPa to 450 MPa, about −300 MPa to about 300 MPa.

After the one or more frontside layer is deposited on the semiconductor wafer, the method continues by depositing a portion of one or more backside layers on the semiconductor wafer in operation 1020. The backside layer may be deposited by using ALD, plasma enhanced ALD, CVD, plasma enhanced CVD, or epitaxial growth. The deposition may take place in a second chamber designed for deposition on a backside of a wafer. At least one of the one or more deposited backside layers is a conductive layer. The conductive layer, as discussed above, may have a sheet resistance of about 5000 ohm/sq or less, e.g., about 100 ohm/sq or less, about 500 ohm/sq or less. In some embodiments, the resistance is about 150 ohm/sq to about 300 ohm/sq. The one or more backside layers may produce internal stress. In some embodiments, the produced internal stress may be able to counteract the internal stress created by the frontside layers deposited in 1010. In these embodiments, the stress by the frontside layer causes the semiconductor wafer to bow. The deposited backside layer may produce internal stress that opposes the stress caused by the frontside. The internal stress caused by the backside may reduce and/or remove wafer bow caused by the internal stress by the frontside layer. By counteracting internal stress, the wafer may remain substantially flat. In some embodiments, the deposited backside layer may have internal stress. The internal stress may be a tensile force of about −1000 MPa to about 1000 MPa, e.g., about −450 MPa to about 450 MPa, about −300 MPa to about 300 MPa. As discussed above, the backside may be a single layer or may be multiple layers. In some embodiments, the backside is homogenous. In some embodiments, the backside layer may be heterogeneous. In either embodiment, part of the deposited backside may be a conductive layer. Examples of a conductive layer is a doped polysilicon. The doped polysilicon may be doped with the dopants listed above.

In operation 1030, a subsequent portion of the frontside is deposited onto the semiconductor substrate. The subsequent portion of the frontside may be deposited on top of a previously deposited portion of the frontside. For example, the previously deposited portion may be the first portion of the frontside deposited in operation 1010. In some embodiments, the previously deposited portion of the frontside layer may be a portion deposited after the first portion of the frontside layer. This will be discussed in more detail below.

The subsequent portion of the frontside layer may be deposited by any suitable technique such as ALD, plasma enhanced ALD, CVD, plasma enhanced CVD, or epitaxial growth. The subsequent portion of the frontside layer may be deposited in the first chamber. In some embodiments, the subsequent portion of the deposited frontside layer is a single layer. In some embodiments, the subsequent portion of the deposited frontside layer is multiple layers. The frontside may produce an internal stress on the semiconductor wafer and, if left uncompensated, may cause the semiconductor wafer to bow. The internal stress caused by the frontside layer may be the internal stress caused by the subsequent portion and all previously deposited portions of the frontside. In some embodiments, the total internal stress of the deposited frontside layer(s) may be about 1000 MPa to about −1000 MPa, e.g., about −450 MPa to about 450 MPa, about −300 MPa to about 300 MPa.

In operation 1040, a subsequent portion of the backside is deposited onto the semiconductor substrate. The subsequent portion of the backside may be deposited on top of a previously deposited portion of the backside. For example, the previously deposited portion may be the first portion of the backside deposited in operation 1020. In some embodiments, the previously deposited portion of the backside layer may be a portion deposited after the first portion of the backside layer. The subsequent portion of the backside layer may be deposited by ALD, plasma enhanced ALD, CVD, plasma enhanced CVD, or epitaxial growth. The subsequent portion may be deposited in the second chamber. In some embodiments, the subsequent portion of the deposited backside layer is a single layer. In some embodiments, the subsequent portion of the deposited backside layer is multiple layers. In some embodiments, the subsequent portion may be the same material as the material of the previously deposited portion. For example, both the previously deposited portion and subsequent portion may be a conductive material, such as a doped polycrystalline film. Similar to operation 1020, the conductive layer may have a sheet resistance of about 5000 ohm/sq or less, e.g., about 1000 ohm/sq or less, about 500 ohm/sq or less. The conductive layer, for example, may have a sheet resistance of about 150 ohm/sq to about 300 ohm/sq. In some embodiments, the subsequent portion and the previously deposited portion may be different materials. In these embodiments, one portion or layer may be a lower resistance than a second portion or layer. For example, the previously deposited portion may be a conductive material, such as doped polycrystalline, and the subsequent portion may be a dielectric material, such as silicon nitride. In some embodiments, the previously deposited portion may be heterogeneous material, and the material of the subsequent portion may a single material. In some such embodiments, the material may match one of the materials in the deposited portion. For example, a previously deposited portion may have a conductive layer and a dielectric layer. The subsequent portion deposited may be a dielectric layer. In another embodiment, the deposited portion may be a homogenous material, and the subsequent portion may be two or more materials. For example, the previously deposited portion may be a conductive material. The subsequent portion may have multiple layers, with one or more layers being the conductive material and other layers being another material such as a dielectric material.

The deposited backside may produce internal stress that opposes the stress caused by the frontside. The deposited backside internal stress may be the combination of the internal stress produced by the previously deposited portions and the internal stress produced by the subsequent portions. The internal stress caused by the deposited backside may reduce and/or remove wafer bow caused by the internal stress from the frontside layer. By counteracting the frontside internal stress with the internal stress of the backside, the wafer may be substantially flat. In some embodiments, the deposited backside layer may have internal stress. The internal stress may be a force of about 1000 MPa to about 1000 MPa, e.g., about −450 MPa to about 450 MPa, about −300 MPa to about 300 MPa.

Operations 1030 and 1040 may be repeated until the frontside is completely deposited. The frontside may be deposited one portion at a time, starting with the first portion in operation 1010, followed by one or more subsequent portions deposited in operation 1030. Each portion may be followed by a backside portion which may counteract the stresses produced by the frontside portion deposited in the immediate previous operation. Depending on the application, the process may cycle between operation 810 for frontside layer deposition and 820 for backside layer deposition for multiple cycles, e.g., 2 cycles, 3 cycles, 5 cycles, 10 cycles, 20 cycles, 50 cycles, 100 cycles, etc. In some embodiments, the process may cycle between chambers, i.e., the semiconductor wafer may be in the first chamber to deposit material on the frontside and in the second chamber to deposit material on the backside of the semiconductor wafer. Once the frontside is completely deposited and the backside is deposited such that the internal stresses of the backside are able to counteract the internal stresses from the frontside such that the wafer is substantially flat, the process may move onto operation 1050.

In operation 1050, the frontside of the unbowed wafer is patterned by photolithography. The frontside may include a target layer and a hardmask. The hardmask may be patterned in the photolithography step to protect selective areas of the frontside layer in subsequent etching operations.

In operation 1060, the semiconductor wafer is placed in an etch chamber and clamped to the ESC via one or more of the backside layers. In some embodiments, the etch chamber may be the same as the first chamber where operations 1010 and 1030 occur. In some embodiments, the etch chamber may be a different chamber than the first chamber. As discussed above, at least a part of the backside is a conductive layer. The conductive layer acts as a first plate, and the ESC act as a second plate of a capacitator. The charge between the two plates produces an electrostatic force able to clamp the semiconductor wafer onto the electrostatic chuck through subsequent processing operations. The conductive layer and the ESC act as a capacitator with the conductive layer acting as a first plate and the platen of the ESC acting as a second plate of a capacitor. This produces an electrostatic force able to clamp the semiconductor wafer onto the electrostatic chuck through subsequent processing operations. To be clamped, the semiconductor wafer should be substantially flat.

In operation 1070, the semiconductor wafer is etched while being clamped to the ESC as described in operation 1050. Example etching processes include plasma etching, reactive ion etching, chemical etching, atomic layer etching, and the like. The etching operation occurs in the etch chamber.

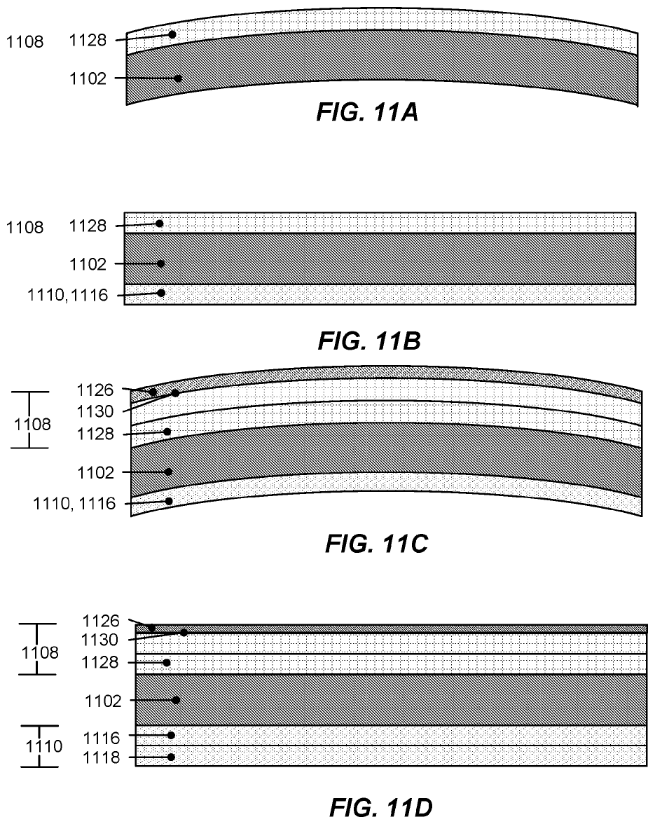

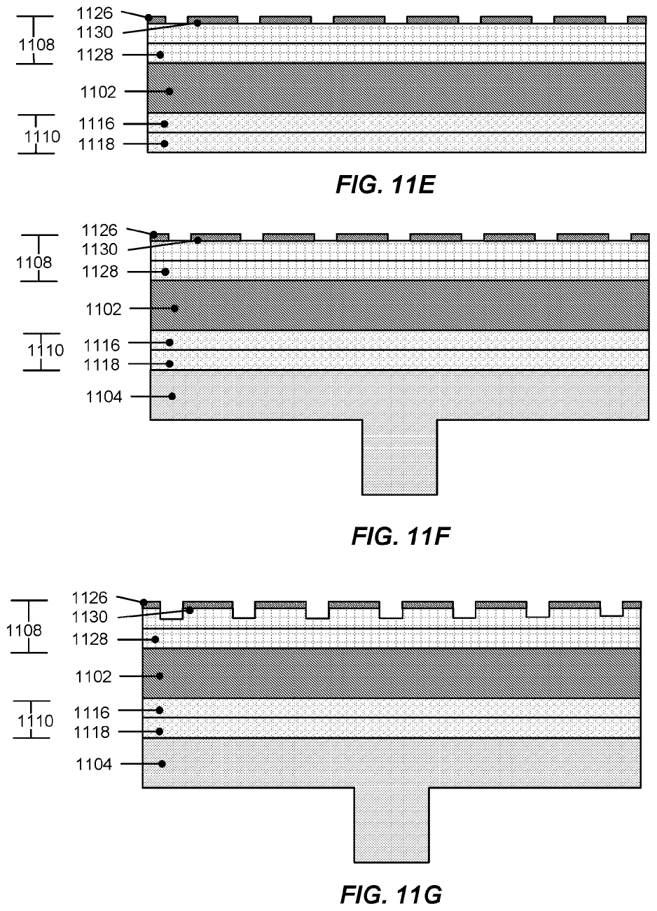

FIGS. 11A-11G show an example schematic of the method depicted in FIG. 10. FIG. 11A shows a semiconductor wafer 1102 after a frontside first portion 1128 of the frontside layer 1108 is deposited in operation 1010. Examples of semiconductor wafer 1102 materials are described above. The frontside first portion 1128, while depicted as a single layer in FIG. 11A, may be a single layer or multiple sublayers. The deposited frontside first portion 1128 may have internal stress, which may cause bowing in the wafer. In the example in FIG. 11A, the frontside layer 1108 and the semiconductor wafer 1102 are bowed, indicating the deposited frontside first portion 1128 has internal stress.

FIG. 11B shows the semiconductor wafer 1102 after a backside first portion 1116 of the backside layer 1110 is deposited in operation 1020. The backside first portion 1116 has internal stress able to counteract the internal stress of the frontside first portion 11288 and may cause the semiconductor wafer 1102 to become substantially flat. In the example shown, the semiconductor wafer 1102, the frontside layer 1108, and the backside layer 1110 are flat. The backside layer 1110, while shown as a single layer in FIG. 11B, may be a single layer or multiple sublayers. Depending on the application, in some embodiments, the backside first portion 1116 may be homogenous. In some embodiments, the backside first portion 1116 may be heterogeneous. In embodiments where the backside first portion 1116 is homogenous, the backside layer may be a conductive material or dielectric material. Examples of conductive materials and dielectric materials are described above.

FIG. 11C shows the semiconductor wafer 1102 after a frontside subsequent portion 1130 is deposited onto frontside layer 1108 in operation 1030. The frontside subsequent portion 1130, while depicted as a single layer in FIG. 11A, may be a single layer or multiple sublayers. In some embodiments, the frontside subsequent portion 1130 may include a hardmask 1126. The deposited frontside subsequent portion 1130 may have internal stress. The internal stress of the frontside layer 1108 may be a combination of the internal stress of each frontside portion deposited onto the semiconductor wafer 1102, e.g., the frontside first portion 1128 and the frontside subsequent portion 1130. After the frontside subsequent portion 1130 is deposited, the internal stress of the frontside layer 1108 may be more than the internal stress of the backside layer 1110. By having an unequal amount of stress on the frontside layer 1108 and backside layer 1110, the semiconductor wafer 1102 may bow, as depicted in FIG. 11C.

FIG. 11D shows the semiconductor wafer 1102 after a backside subsequent portion 1118 is deposited onto the backside layer 1110 in operation 1040. The backside subsequent portion 1118 may have internal stress. The internal stress of the backside layer 1110 may be a combination of the internal stress of each backside portion deposited onto the semiconductor wafer, e.g., the backside first portion 1116 and the backside subsequent portion 1118. The new internal stress of the backside layer 1110 may be able to counteract the internal stress caused by the frontside layer 1108 and may cause the semiconductor wafer 1102 to become substantially flat. In the example shown, the semiconductor wafer 1102, the frontside layer 1108, and the backside layer 1110 are flat. Depending on the application, in some embodiments, the backside first portion 1116 may be homogenous. In some embodiments, the backside first portion 1116 may be heterogeneous. In embodiments where the backside first portion 1116 is homogenous, the backside layer may be a conductive material or dielectric material. The backside layer 1110 may be homogenous or heterogeneous. When the backside layer 1110 is homogenous, the backside layer is made of a conductive material. When the backside layer 1110 is heterogeneous, the backside layer has at least one sublayer that is made of a conductive material. With a heterogeneous backside, the backside layer has two or more layers. In this embodiment, at least a first backside layer has a sheet resistance lower than a sheet resistance of a second backside layer. In some embodiments of a heterogeneous backside layer (e.g., backside layer 1110), one sublayer may be a dielectric. Generally speaking, with a heterogeneous backside layer (e.g., backside layer 1110) with a conductive material and a dielectric material, the conductive material may be closer to the semiconductor wafer 1102. For example, if the backside layer 1110 was heterogeneous in FIG. 11D, the backside first portion 1116 may be a conductive material, and the backside subsequent portion 1118 may be a dielectric material.

FIG. 11E shows the semiconductor wafer 1102 after the frontside layer 1108 is patterned by photolithography in operation 1050. In the embodiment shown, the frontside layer 1108 has a hardmask 1126. The photolithography operation patterns the hardmask 1126 in preparation for subsequent etch operations.

FIG. 11F shows the semiconductor wafer 1102 clamped to the ESC 1104 as described in operation 1060. The semiconductor wafer 1102 is held by the electrostatic force between the ESC 1104 and the backside layer 1110. The electrostatic force secures the semiconductor wafer 1102 to the ESC 1104, preventing the semiconductor wafer from dechucking or slipping off the ESC in subsequent operations.

FIG. 11G shows the semiconductor wafer 1102 after the etch operations in 1070 take place. Example etch operations are discussed above. In the embodiment shown, the etch operation etches the frontside layer 1108, following the pattern created in the hardmask 1126 by the photolithography in operation 1050.

### Apparatus

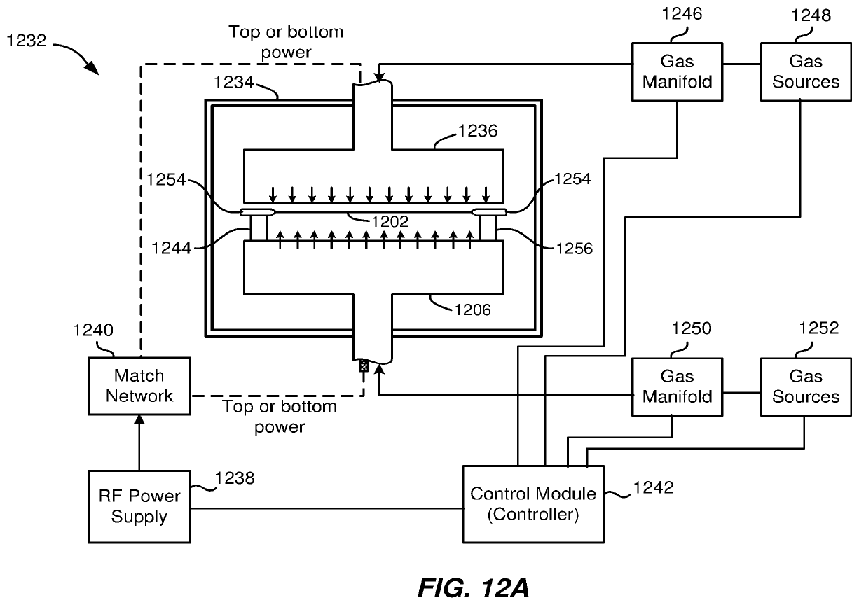

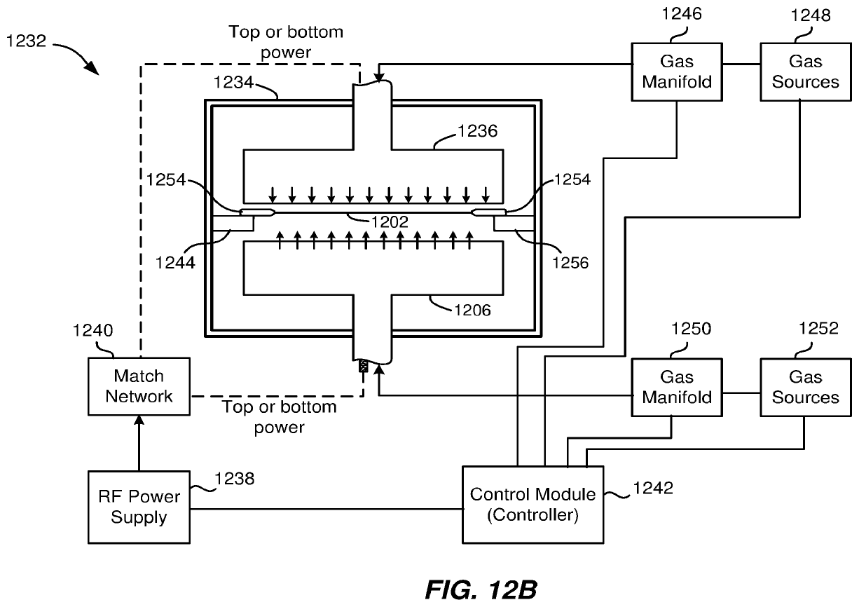

FIG. 12A is a block diagram that illustrates a substrate processing system 1200 used to perform processing on a wafer 1202 (also referred to as a wafer), according to some embodiments. As shown, the substrate processing system may include a chamber 1234. A center column may be configured to support a pedestal for when a top surface of the wafer 1202 is being processed, e.g., a film is being formed on the top surface of the wafer 1202, or on the backside of the wafer 1202. The pedestal, in accordance with some embodiments disclosed herein, may be referred to as a showerhead-pedestal (“ShoPed”) 1206. A showerhead 1236 may be disposed over the ShoPed 1206.

In some embodiments, the showerhead 1236 may be electrically coupled to power supply 1238 via a match network 1240. The power supply 1238 may be controlled by a control module 1242, e.g., a controller. In some embodiments, power may be provided to the ShoPed 1206 instead of the showerhead 1236. The control module 1242 may be configured to operate the substrate processing system 1232 by executing process input and control for specific process recipes. Depending on whether the top surface of the wafer 1202 is receiving a deposited film or the bottom surface of the wafer 1202 is receiving a deposited film, the controller module 1242 may set various operational inputs for a process recipe, such as power levels, timing parameters, process gasses, mechanical movement of a wafer 1202, and/or the height of the wafer 1202 relative to the ShoPed 1206.

In some embodiments, the center column may also include lift pins, which are controlled by a lift pin control. Such lift pins may be used to raise the wafer 1202 from the ShoPed 1206 to allow an end effector (not shown) to pick the wafer and to lower the wafer 1202 after being placed by the end effector. The end effector may also place the wafer 1202 over spacers 1244. As will be described below, the spacers 1244 may be sized to provide a controlled separation of the wafer 1202 between a top surface of the showerhead 1236 (facing the wafer) and a top surface of the ShoPed 1206 (facing the wafer).

In some embodiments, the substrate processing system 1232 may further include a first gas manifold 1246 that is connected to first gas sources 1248, e.g., gas chemistry supplies from a facility and/or inert gases. Depending on the processing being performed over a top surface of the wafer 1202, the control module 1242 may controls the delivery of first gas sources 1248 via the first gas manifold 1246. The chosen gases may then be flown into the showerhead 1236 and distributed in a space volume defined between a face of the showerhead 1236 that faces that wafer 1202 when the wafer is resting over the pedestal.

In some embodiments, the substrate processing system 1232 may further include a second gas manifold 1250 that is connected to second gas sources 1252, e.g., gas chemistry supplies from a facility and/or inert gases. Depending on the processing being performed over a bottom surface of the wafer 1202, the control module 1242 may control the delivery of second gas sources 1252 via the second gas manifold 1250. The chosen gases may then be flown into the showerhead 1236 and distributed in a space volume defined between a face of the ShoPed 1206 that faces an under surface or under side (e.g., backside) of the wafer 1202 when the wafer is resting over the spacers 1244. The spacers 1244 may provide for a separation that optimizes deposition to the under surface of the wafer 1202, while reducing deposition over the top surface of the wafer 1202. In some embodiments, while deposition is targeted for the under surface of the wafer 1202, an inert gas may be flown over the top surface of the wafer 1202 via the showerhead 1236, which may push reactant gases away from the top surface and enable reactant gases provided from the ShoPed 1206 to be directed to the under surface of the wafer 1202.

Further, the gases may be premixed or not. Appropriate valving and mass flow control mechanisms may be employed to ensure that the correct gases are delivered during the deposition and plasma treatment phases of the process. Process gases may exit the chamber 1234 via an outlet. A vacuum pump (e.g., a one or two stage mechanical dry pump and/or a turbomolecular pump) may draw process gases out and maintains a suitably low pressure within the reactor by a close loop-controlled flow restriction device, such as a throttle valve or a pendulum valve.

In some embodiments, a carrier ring 1254 may encircle an outer region of the ShoPed 1206. When the top surface of the wafer 1202 is being processed, e.g., a material is being deposited thereon, the carrier ring 1254 may be configured to sit over a carrier ring support region that is a step down from a wafer support region in the center of the pedestal ShoPed 1206. The top surface of the carrier ring 1254 is generally coplanar with the top surface of the wafer 1202. The carrier ring 1254 may include an outer edge side of its disk structure, e.g., outer radius, and a wafer edge side of its disk structure, e.g., inner radius, that is closest to where the wafer 1202 sits. The carrier ring 1254 may be associated with an inner diameter (ID). The inner diameter may extend to an inner perimeter of the carrier ring and generally surround a substrate (e.g., wafer 1202) in a processing chamber. The wafer edge side of the carrier ring 1254 may also include a plurality of contact support structures or “tabs” which may be configured to lift the wafer 1202 when the carrier ring 1254 is held by the spacers 1244. The carrier ring 1254 may include a plurality of tabs with a quantity selected from a range to support the wafer 1202 during processing. Additional details regarding embodiments of the tabs will follow.

FIG. 12B is a block diagram that illustrates another substrate processing system 1232 used to perform processing on the wafer 1202, according to some embodiments. In some embodiments, spider forks 1256 may be used to lift and maintain the carrier ring 1254 in its process height, e.g., to allow depositing in the under surface (backside) of the wafer 1202. The carrier ring 1254 may therefore be lifted along with the wafer 1202. In some implementations, the carrier ring 1254 may be rotated to another station, e.g., in a multi-station system.

Broadly speaking, the embodiments disclosed herein are for a system to deposit PECVD films on the selective side of the wafer (front and/or back) with dynamic control. Some embodiments may include a dual gas-flowing electrode for defining a capacitively-coupled PECVD system. The system may include a gas-flowing showerhead (e.g., showerhead 1236) and a ShoPed 126. In some embodiments, the gas-flowing pedestal (i.e., ShoPed) is a combination showerhead and pedestal, which enables deposition on a back-side of the wafer. The electrode geometry combines features of a showerhead, e.g., a gas mixing plenum, holes, hole-pattern, gas jet preventing baffle, and features of a pedestal. Examples of features of a pedestal include an embedded controlled heater, wafer-lift mechanisms, ability to hold plasma suppression rings, and movability. This enables the transfer of wafers and the processing of gasses with or without RF power from the pedestal.

In some embodiments, the system may have a wafer lift mechanism that tightly controls parallelism of the substrates against the electrodes. In one example, this may be achieved by setting up the lift mechanism parallel to the two electrodes and controlling manufacturing tolerances, e.g., spindle or lift pins mechanisms. In another example, the lift may be achieved by raising the wafer lift parts. This option may not allow dynamic control of the side that gets deposited.

In some configurations, the lift mechanism may allow dynamically controlling the substrate position during processing (before plasma, during plasma, after plasma) to control the side of the deposition, profile of the deposition, and deposition film properties. The system may further allow selective enabling/disabling of the side where reactants are flown. One side can flow the reactant and the other side can flow inert gases to suppress the deposition and plasma.

In some embodiments, the gap between the side of the wafer that does not need plasma/dep may be tightly controlled. This distance may be controlled to suppress plasma. By not controlling the distance, the wafer may be susceptible to plasma damage. For example, the system may allow a minimal gap from about 2 mm to about 0.5 mm, and in another embodiment from about 1 mm to about 0.05 (limited by the wafer bow), and such gap can be controlled. The gap maybe controlled depending on process conditions.

In some embodiments, the gas-flowing pedestal (i.e., ShoPed) may enable, without limitation: (a) thermal stabilization of the wafer to processing temperature prior to processing; (b) selective design of hole patterns on the ShoPed to selectively deposition film in different areas of the back-side of the wafer; (c) swappable rings can be attached to achieve appropriate plasma confinement and hole pattern; (d) stable wafer transfer mechanisms within chamber and for transferring wafer outside to another chamber or cassette-such as lift pins, RF-coupling features, minimum-contact arrays; (e) implement gas mixing features, e.g., such as inner plenum, baffle and manifold lines openings; and (f) add compartments in the gas-flowing pedestal (i.e., ShoPed) to enable selective gas flow to different regions of the back side of the wafer and control flow rates via flow controllers and/or multiple plenums.

In another embodiment, dynamic gap control using wafer lift mechanism enables: (a) control of the distance from deposition or reactant flowing electrode to the side of the wafer that needs deposition or in the middle so that both sides can be deposited; and (b) the lift mechanism to control the distance dynamically during the process (before plasma, during plasma, after plasma) to control the side of the deposition, profile of the deposition, and deposition film properties. In another embodiment, for a deposition mode used to deposit on the backside of the wafer, film edge exclusion control is highly desirable to avoid lithography-related overlay problems. The lift mechanism used in this system is done via a carrier ring 124 that has a design feature to shadow the deposition on the edge. This specifies the edge exclusion control via the design and shape of the carrier ring.

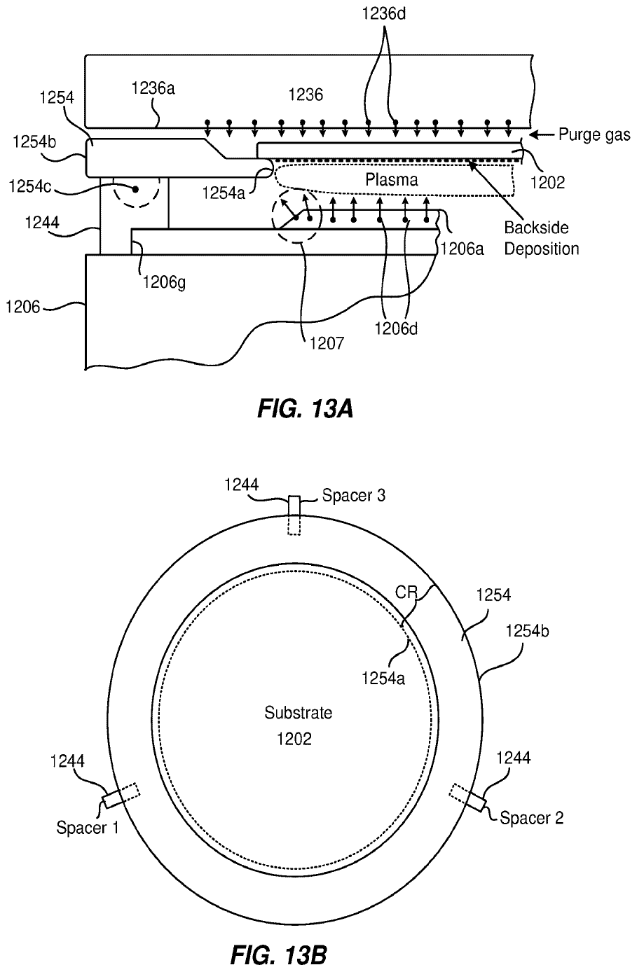

FIG. 13A shows a cross-sectional view of an edge region of the ShoPed 1206. This view provides a cross-sectional representation of the carrier ring 1254, which has a carrier ring inner radius 1254a and a carrier ring outer radius 1254b. In some embodiments, the carrier ring 1254 includes support extensions 1254c, which extend below the substantial flat surface of the carrier ring 1254.

The support extensions 1254c are configured to mate and sit within support surfaces defined into a top surface of the spacers 1244. The support surfaces provide a complementary mating surface for the support extensions 1254c, such that the carrier ring 1254 is prevented from sliding or moving when supported by the spacers 1244. Although three spacers are shown as spacers 1244 are shown in FIG. 13B, it is envisioned that any number of spacers may be provided, so long as the carrier ring can be supported substantially parallel to the surface of the ShoPed 1206, and spacing is defined for supporting wafer 1202 at a spaced apart relationship from a top surface of the ShoPed 1206.

Further shown is that a top surface of the ShoPed 1206 will include a hole pattern 1206a that is distributed throughout the surface to provide even distribution and output of gases during operation. In one embodiment, the hole pattern 1206a is distributed in a plurality of concentric rings that start at the center of the top surface of the ShoPed 1206 and extend to an outer periphery of the ShoPed 1206. At least one hole pattern 1206a is provided at an edge hole region 1207 of the hole pattern, and orifices defined in the edge hole region 1207 are preferably angled to provide gases non-perpendicular to the surface of the ShoPed 1206.

In one example, the angle or tilt at which the orifices in the edge hole region 1207 is defined to tilt or angle away from the center of the ShoPed 106. In one embodiment, the angle is approximately 45° from horizontal. In other embodiments, the angle can vary between 20° from horizontal to about 80° from horizontal. In one embodiment, by providing the angled orifices in the edge hole region 1207, additional distribution of process gases can be provided during backside deposition of the wafer 1202. In one embodiment, the remainder orifices 1206d of the hole pattern 1206a are oriented substantially perpendicular to the surface of the ShoPed 106 and directed toward the underside of the wafer 1202.

FIG. 13B illustrates that when the wafer 1202 is held by the carrier ring 1254, the wafer 1202 edge will sit on an edge region closer to the carrier ring inner radius 1254a of the carrier ring 1254. The surface of the showerhead 1236 facing the top surface of the wafer 1202, when positioned using spacers 1244, may be substantially close to prevent deposition during a mode where deposition is being carried out to the backside of the wafer 1202.

By way of example, the distance between the top of the wafer 1202 and the surface of the showerhead 1236 is preferably between about 2 mm to about 0.5 mm, and in some embodiments about 1 mm to about 0.5 mm, depending on the wafer bow. That is, if the wafer is bowed substantially, the separation will be about 0.5 mm or larger. If the wafer is not yet bowed substantially, the separation can be less than about 0.5 mm. In one embodiment, it is preferable that the separation be minimized to prevent deposition on the top side of the substrate when the backside of the substrate is being deposited with a layer of material. In some embodiments, the showerhead 1236 is configured to supply an inert gas flow over the top side of the wafer 1202 during when the backside of the substrate is being deposited and deposition gases are being supplied by the ShoPed 1206.

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems.

In some embodiments, a first deposition may be performed at a first station that is one of two, five, or even more deposition stations positioned within a single deposition chamber. Thus, for example, hydrogen (H₂) and tungsten hexafluoride (WF₆) may be introduced in alternating pulses to the surface of the semiconductor substrate, at the first station, using an individual gas supply system that creates a localized atmosphere at the substrate surface. Another station may be used for NF₃ treatment, and a third and/or fourth for subsequent ALD bulk fill.

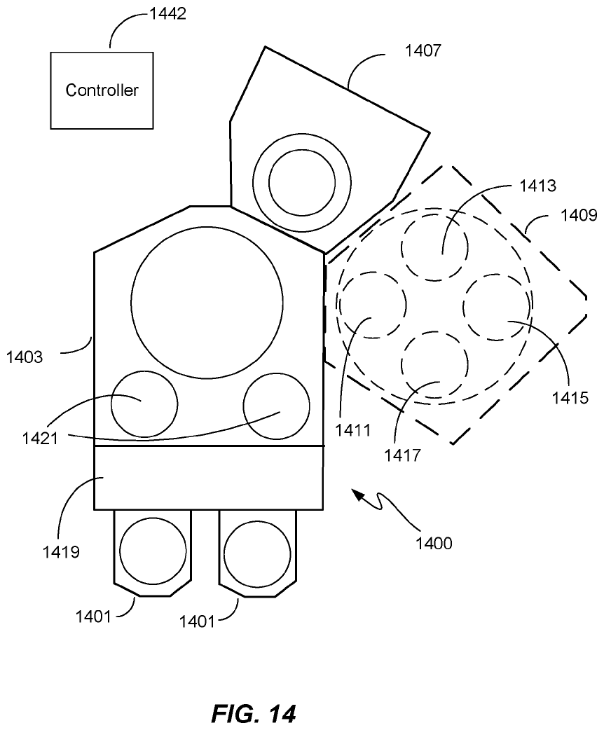

FIG. 14 is a schematic of a process system suitable for conducting deposition processes in accordance with embodiments. The system 1400 includes a transfer module 1403. The transfer module 1403 provides a clean, pressurized environment to minimize risk of contamination of substrates being processed as they are moved between various reactor modules. Mounted on the transfer module 1403 is a multi-station reactor 1409 capable of performing ALD, treatment, and CVD according to various embodiments. Multi-station reactor 1409 may include multiple stations 1411, 1413, 1415, and 1417 that may sequentially perform operations in accordance with disclosed embodiments. For example, multi-station reactor 1409 may be configured such that station 1411 performs a frontside deposition using a precursor and a reducing agent, station 1413 performs an ALD bulk deposition of a conformal layer using a reducing agent, station 1415 performs a NF₃ treatment operation, and station 1417 may perform a bulk ALD fill after treatment using a reducing agent.

Stations may include a heated pedestal or substrate support, one or more gas inlets or showerhead or dispersion plate.

Returning to FIG. 14, also mounted on the transfer module 1403 may be one or more single or multi-station modules 1407 capable of performing plasma or chemical (non-plasma) pre-cleans, other deposition operations, or etch operations. The module may also be used for various treatments to, for example, prepare a substrate for a deposition process. The system 1400 also includes one or more wafer source modules 1401, where wafers are stored before and after processing. An atmospheric robot (not shown) in the atmospheric transfer chamber 1419 may first remove wafers from the source modules 1401 to loadlocks 1421. A wafer transfer device (generally a robot arm unit) in the transfer module 1403 moves the wafers from loadlocks 1421 to and among the modules mounted on the transfer module 1403.

In various embodiments, a system controller 1442 is employed to control process conditions during deposition. The system controller 1442 will typically include one or more memory devices and one or more processors. A processor may include a CPU or computer, analog and/or digital input/output connections, stepper motor controller boards, etc.

The system controller 1442 may control all of the activities of the deposition apparatus. The system controller 1442 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the system controller 1442 may be employed in some embodiments.

Typically, there will be a user interface associated with the system controller 1442. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 1442. The signals for controlling the process are output on the analog and digital output connections of the system 1400.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a system controller 1442 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 1442, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 1442, in some implementations, may be a part of or coupled to a computer that is integrated with, coupled to the system, otherwise networked to the system, or a combination thereof. For example, the system controller 1442 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The system controller 1442 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of processing a semiconductor substrate during fabrication of an electronic device, the method comprising:
(a) depositing one or more frontside layers on the semiconductor substrate that have a frontside internal stress that, if uncompensated, produces bowing of the semiconductor substrate; and
(b) depositing one or more backside layers on the semiconductor substrate that have a backside internal stress that counteracts the frontside internal stress of the one or more frontside layers and reduces or eliminates the bowing, wherein the one or more backside layers have a sheet resistance equal to or less than about 5000 ohm/sq.

2. The method of claim 1, further comprising (c) clamping, via an electrostatic chuck, the semiconductor substrate with the one or more backside layers.

3. The method of claim 2, further comprising (d) etching the semiconductor substrate while the semiconductor substrate is clamped to the electrostatic chuck.

4. The method of claim 2, wherein operations (a), (b), and (c) are each performed in a different chamber.

5. The method of claim 1, wherein the one or more frontside layers comprise a hardmask.

6. The method of claim 1, wherein the one or more backside layers have a thickness of about 1 μm to about 10 μm.

7. The method of claim 1, wherein one of the one or more backside layers has a sheet resistance of about 150 ohms/square to about 300 ohms/square.

8. The method of claim 1, wherein at least one of the one or more backside layers comprises a doped polysilicon.

9. The method of claim 8, wherein the doped polysilicon is doped with a dopant comprising phosphorus, carbon, boron, tungsten, nitrogen, or any combination of two or more thereof.

10. The method of claim 1, wherein the backside internal stress of the one or more backside layers is about −300 MPa to about 300 MPa.

11. The method of claim 1, wherein depositing one or more backside layers comprises depositing a first backside layer and a second backside layer, disposed further toward an outside of the semiconductor substrate than the first backside layer, and wherein the sheet resistance of the first backside layer is lower than the sheet resistance of the second backside layer.

12. The method of claim 1, wherein depositing one or more backside layers on the semiconductor substrate comprises exposing the semiconductor substrate to a process gas comprising a silicon precursor and a dopant precursor, and
wherein the method further comprises annealing the semiconductor substrate at a temperature of about 700° C. to about 900° C. to convert a deposited doped silicon layer to a doped polysilicon layer.

13. A semiconductor substrate or an electronic device comprising:
(a) one or more frontside layers that have a frontside internal stress that, if uncompensated, produces bowing of the semiconductor substrate or the electronic device; and
(b) one or more backside layers that have a backside internal stress that counteracts the frontside internal stress of the one or more frontside layers and reduces or eliminates the bowing, wherein the one or more backside layers have a sheet resistance equal to or less than about 5000 ohm/sq.

14. The semiconductor substrate or the electronic device of claim 13, wherein the one or more backside layers have a thickness of about 1 μm to about 10 μm.

15. The semiconductor substrate or the electronic device of claim 13, wherein the sheet resistance of the one or more backside layers is about 500 ohm/sq or less.

16. The semiconductor substrate or the electronic device of claim 13, wherein the sheet resistance of the one or more backside layers is about 150 ohm/sq to about 300 ohm/sq.

17. The semiconductor substrate or the electronic device of claim 13, wherein at least one of the one or more backside layers comprises a doped polysilicon.

18. The semiconductor substrate or the electronic device of claim 17, wherein the doped polysilicon is doped with a dopant comprising phosphorus, carbon, boron, tungsten, nitrogen, or any combination of two or more thereof.

19. The semiconductor substrate or the electronic device of claim 13, wherein the backside internal stress of the one or more backside layers is about −300 MPa to about 300 MPa.

20. The semiconductor substrate or the electronic device of claim 13, wherein the one or more backside layers comprise a first backside layer and a second backside layer, disposed further toward an outside of the semiconductor substrate than the first backside layer, and the sheet resistance of the first backside layer is lower than the sheet resistance of the second backside layer.

21-29. (canceled)

30. An apparatus comprising:
a process chamber;
a substrate support;
a showerhead;
a gas source fluidically connected to the showerhead; and
a controller configured to cause:
(a) receiving a semiconductor substrate having one or more frontside layers having a frontside internal stress that, if uncompensated, produces bowing of the semiconductor substrate; and
(b) depositing one or more backside layers on the semiconductor substrate that have a backside internal stress that counteracts the frontside internal stress of the one or more frontside layers and reduces or eliminates the bowing, wherein the one or more backside layers have a sheet resistance equal to or less than about 5000 ohm/sq.

31-39. (canceled)
